(19) United States
(12) Patent Application Publication
(10) Pub. No.: US 2008/0128776 A1
(43) Pub. Date: Jun. 5, 2008

(54) NON-VOLATILE ROM AND METHOD OF FABRICATING THE SAME

(75) Inventor: Ki-Seog KIM, Seoul (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Icheon-si (KR)

(21) Appl. No.: 11/748,107

(22) Filed: May 14, 2007

(30) Foreign Application Priority Data
Dec. 4, 2006 (KR) 2006-121601

(51) Int. Cl. H01L 29/788; H01L 21/336

(52) U.S. Cl. 257/315; 438/260; 257/E21.409; 257/E29.3

(57) ABSTRACT

The NROM includes a plurality of gate patterns, a plurality of junction regions, first contact plugs, second contact plugs, first metal lines and second metal lines. Each of the plurality of gate patterns has a dielectric layer and gate conductive layers sequentially stacked over a semiconductor substrate. The plurality of junction regions is isolated from the gate conductive layers in active regions between the plurality of gate patterns. The first contact plugs are respectively connected to first junction regions of a diagonal direction of the plurality of junction regions. The second contact plugs are respectively connected to second junction regions of a diagonal direction other than the first junction regions. The first metal lines connect the first contact plugs that are adjacent to each other in a diagonal direction. The second metal lines connect the second contact plugs that are adjacent to each other in a diagonal direction.

### CROSS-REFERENCES TO RELATED APPLICATIONS

The present application claims priority to Korean patent application number 10-2006-121601, filed on Dec. 4, 2006, which is incorporated by reference in its entirety.

### BACKGROUND OF THE INVENTION

The present invention relates, in general, to a Non-volatile ROM (NROM) and, more particularly, to a NROM and a method of fabricating the same, in which process steps can be reduced and line margin can be increased.

NROM is a known NROM device in which charges are stored in the dielectric layer.

FIG. 1 is a cross-sectional view of a conventional NROM.

NROM is formed on a silicon substrate 1 having a first conductive type. First and second regions 2 and 3, which have a second conductive type (N⁺ bit line) different from the first conductive type (N⁺ bit line), are spaced apart from each other. The first region 2 is separated from the second region 3 by a channel region 4.

A bit line oxide layer 5 of silicon oxide or silicon dioxide is formed on the channel region 4. A dielectric material 6 is disposed on the bit line oxide layer 5. On the dielectric material 6 is disposed an insulating layer 7. The bit line oxide layer 5, the dielectric layer 6 and the insulating layer 7 are collectively referred to as an “ONO layer 5-7”.

A polysilicon gate 8 is disposed on the insulating layer 7. Thus, the dielectric material 6 is separated and insulated from the channel region 4 by means of the bit line oxide layer 5. The polysilicon gate 8 is separated and insulated from the dielectric material 6 by means of the insulating layer 7. In summary, the polysilicon gate 8 is separated and insulated from the channel region 4 by means of the ONO layer 5-7.

NROM is a double-density, non-volatile storage cell capable of storing 2-bit information in a cell. The polysilicon layer 8 serves as a gate, and controls the flow of current between the first region 2 and the second region 3 through the channel region 4.

In order to program one of bits, the polysilicon gate 8 has a rising positive voltage. The first region 2 keeps grounded or close to the ground, and the second region 3 has a rising positive voltage. Electrons from the first region 2 are accelerated into the channel region 4 toward the second region 3, and are injected through the bit line oxide layer 5 in accordance with a hot channel electron implantation mechanism, and are trapped at the dielectric material 6 near a region 9 of the dielectric layer 6. Since the dielectric layer 6 formed of silicon nitride is non-conductive, charges are trapped at the region 9.

In order to program other bits, the polysilicon layer 8 has a rising positive voltage. The second region 3 keeps grounded or close to the ground, and the first region 2 has a rising positive voltage. Electrons from the second region 3 are accelerated into the channel region 4 toward the first region 2, and are injected through the bit line oxide layer 5 in accordance with a hot channel electron implantation mechanism, and are trapped at a region 10 of the dielectric material 6. Since the dielectric layer 6 is non-conductive, charges are trapped at the region 10.

The above NROM requires a thick insulating layer (oxide layer) in the N⁺ bit line region in order to isolate the word line gate and the N⁺ bit line in a cell structure. The need for the growth of the insulating layer causes to hinder high integration of devices due to a bird's beak phenomenon.

Further, in the conventional process, after the N⁺ bit line is formed by means of an ion implantation process, the ONO layer 5-7 is deposited to form a pattern and an oxidization process is then performed to form the oxide layer 5 for isolating the word line gate and the junction. Thereafter, material to be used as the gate is deposited and patterned. In this case, high integration becomes difficult due to the diffusion of the N⁺ bit line and the bird's beak phenomenon, caused by the oxidization process for forming the oxide layer 5.

### SUMMARY OF THE INVENTION

Accordingly, the present invention addresses the above problems, and discloses NROM and a method of fabricating the same, in which a dielectric layer and a gate conductive layer formed over a semiconductor substrate are etched to form a pattern, and an ion implantation process is then performed on an exposed semiconductor substrate to form a junction region, so that the gate conductive layer and the junction region can be isolated from each other without an insulating layer and contacts are formed twice in a diagonal direction, increasing line margin.

According to an aspect of the present invention, there is provided NROM including a plurality of gate patterns, a plurality of junction regions, first contact plugs, second contact plugs, first metal lines and second metal lines. Each of the plurality of gate patterns has a dielectric layer and gate conductive layers sequentially stacked over a semiconductor substrate. The plurality of junction regions is isolated from the gate conductive layers in active regions between the plurality of gate patterns. The first contact plugs are respectively connected to first junction regions of a diagonal direction, which are not adjacent to one another, of the plurality of junction regions. The second contact plugs are respectively connected to second junction regions of a diagonal direction, which are not adjacent to one another, other than the first junction regions of the plurality of junction regions. The first metal lines connect the first contact plugs that are adjacent to each other in a diagonal direction. The second metal lines connect the second contact plugs that are adjacent to each other in a diagonal direction.

According to another aspect of the present invention, there is provided a method of fabricating NROM, including the steps of forming trenches in a semiconductor substrate and filling the trenches with an insulating layer to form isolation structures, forming a dielectric layer in an active region of the semiconductor substrate, forming gate conductive layers on the entire surface including the dielectric layer, and etching the gate conductive layers in a direction of word lines to form gate patterns through which specific regions of the semiconductor substrate are exposed, forming an insulating layer on the entire surface including the gate patterns, etching the insulating layer so that the insulating layers are not adjacent to each other in a diagonal direction, forming first contact plugs, forming first metal lines to connect the first contact plugs, etching the insulating layers in which the first contact plugs are not formed, forming second contact plugs, and forming second metal lines to connect the second contact plugs.

### BRIEF DESCRIPTION OF THE DRAWINGS

FIG. 1 is a cross-sectional view of a conventional NROM; and

FIGS. 2 to 10 are cross-sectional views and layout diagrams of a NROM according to an embodiment of the present invention.

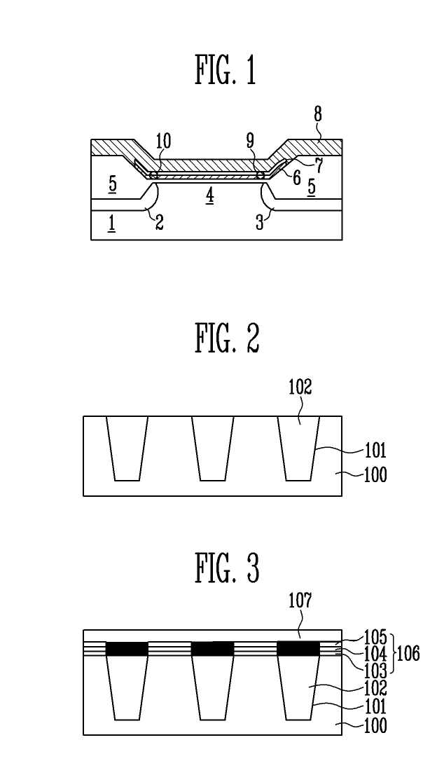

### DESCRIPTION OF SPECIFIC EMBODIMENTS

Now, specific embodiments according to the present invention will be described with reference to the accompanying drawings.

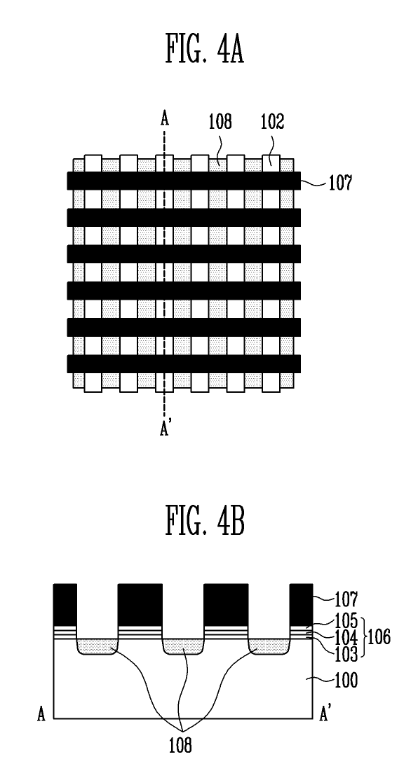

FIGS. 2 to 10 are cross-sectional views and layout diagrams illustrating a method of fabricating a NROM according to an embodiment of the present invention.

Referring to FIG. 2, trenches 101 are formed in a semiconductor substrate 100 by an etch process. An insulating layer is formed on the semiconductor substrate including the trenches 101. Then, a planarization process is then performed to form isolation structures 102.

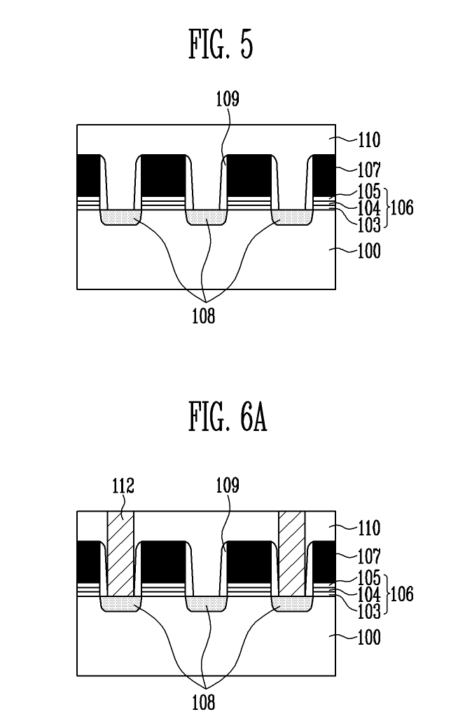

Referring to FIG. 3, a first oxide layer 103, a nitride layer 104 and a second oxide layer 105 are sequentially formed over the semiconductor substrate including the isolation structures 102. An etch process is performed so that the first oxide layer 103, the nitride layer 104 and the second oxide layer 105 remain in an active region, that is, a region in which the isolation structures 102 are not formed, forming a dielectric layer 106. Gate conductive layers 107 are formed over the isolation structures 102 and the dielectric layer 106. The gate conductive layers 107 can be formed of a polysilicon layer. The isolation layer has an ONO (oxide-nitride-oxide) structure formed of a first oxide layer, a nitride layer and a second oxide layer.

Referring to FIGS. 4A and 4B, the gate conductive layers 107 are etched by means of an etch process employing an etch mask so that they have a pattern vertical to the isolation structures 102. An ion implantation process is then performed in an exposed semiconductor substrate 100 to form junction regions 108. Thus, the junction regions 108 and the gate conductive layers 107 are formed with the dielectric layer 106 intervened there between, and the junction regions 108 are formed in the regions from which the gate conductive layers 107 have been etched. Accordingly, an insulating layer for electrically separating the junction regions 108 and the gate conductive layers 107 is not formed.

Referring to FIG. 5, a spacer 109 is formed over the sidewalls of the gate conductive layers 107 and the dielectric layer 106. An insulating layer 110 is then formed over the semiconductor substrate including the spacer 109 an gate conductive layers 107.

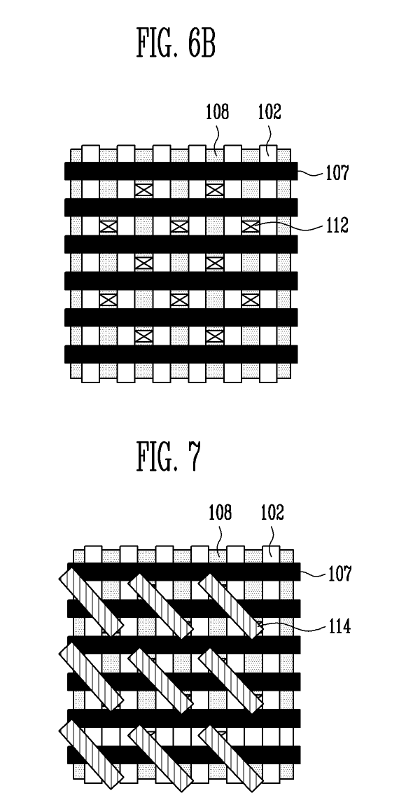

Referring to FIG. 6A, an etch process is performed so that the junction regions 108 are partially exposed, to form contact holes. The exposed junction regions 108 are not adjacent to one another in the directions of bit lines and word lines. The contact holes are filled with contact material to form first contact plugs 112.

FIG. 6B is a layout diagram of a device on which the same process as that in FIG. 6A is performed.

Referring to FIG. 6B, first contact plugs 112 are formed with one junction region 108 intervened there between. That is, the first contact plugs 112 are formed in a diamond shape.

Referring to FIG. 7, first metal lines 114 to connect the first contact plugs 112 are formed in a diagonal direction. In other words, the first metal lines 114 connect the first contact plugs 112 in a diagonal direction of neighboring bit lines. Thus, as the first metal lines 114 are formed in a diagonal direction, the length of a line can be increased compared with when the first metal lines 114 are formed in the direction of the bit line, so that process margin is increased.

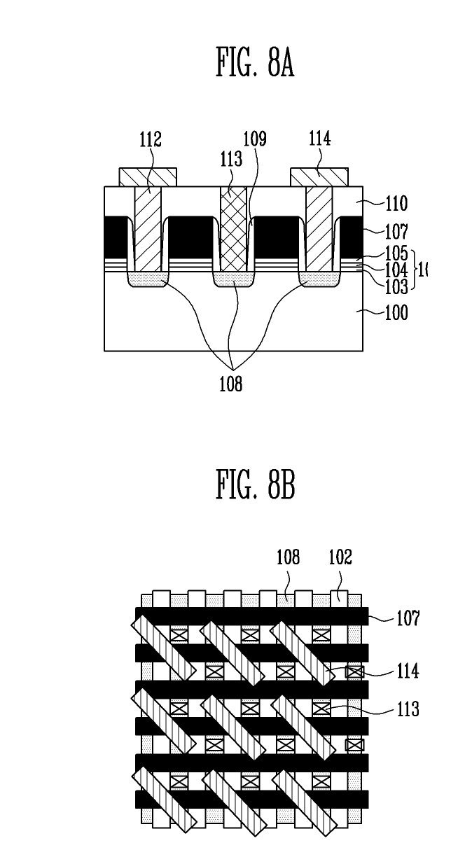

Referring to FIGS. 8A and 8B, an etch process for exposing the non-exposed junction regions 108 is performed to form contact holes. The contact holes are buried to form second contact plugs 113. That is, the second contact plugs 113 are formed in a diamond shape.

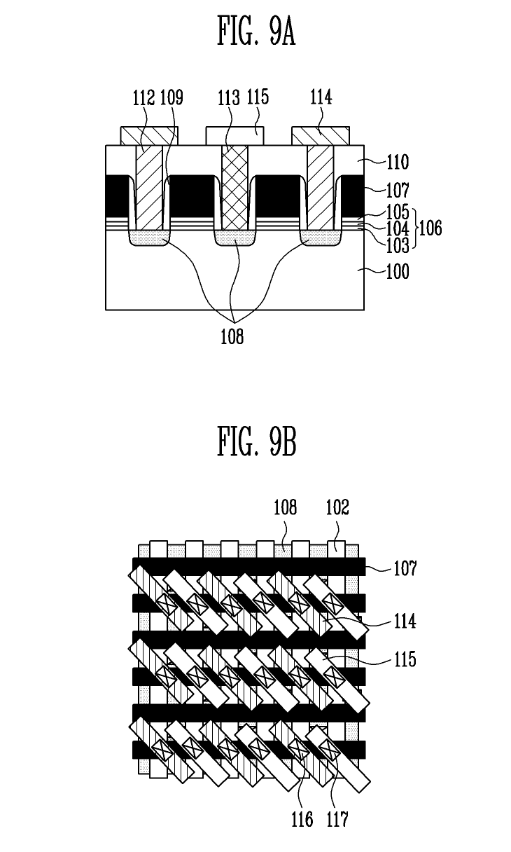

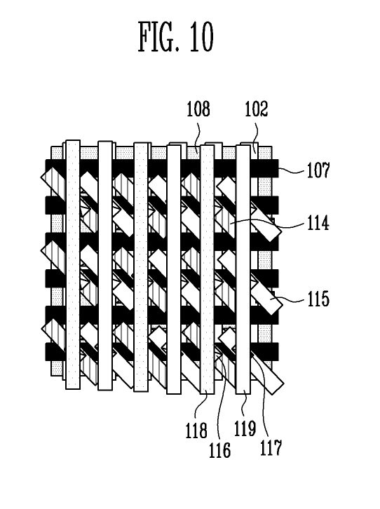

Referring to FIGS. 9A and 9B, second metal lines 115 to connect the second contact plugs 113 are formed in a diagonal direction. That is, the second metal lines 115 connect the second contact plugs 113 in a diagonal direction of neighboring bit lines. Thus, as the second metal lines 115 are formed in a diagonal direction, the length of a line can be increased compared with when the second metal lines 115 are formed in the direction of the bit line, so that process margin can be increased. Third contact plugs 116 and 117 to connect the first metal lines 114 and the second metal lines 115 are then formed.

Referring to FIG. 10, third metal lines 118 and fourth metal lines 119 to connect the contact plugs 116 and 117 are formed in the direction of the bit lines.

As described above, according to the present invention, a dielectric layer and a gate conductive layer formed over a semiconductor substrate are etched to form a pattern. An ion implantation process is then performed on an exposed semiconductor substrate to form a junction region. Accordingly, the gate conductive layer and the junction region can be isolated from each other without an insulating layer and contacts are formed twice in a diagonal direction. It is therefore possible to increase line margin.

Although the foregoing description has been made with reference to the specific embodiments, it is to be understood that changes and modifications of the present invention may be made by the ordinary skilled in the art without departing from the spirit and scope of the present invention and appended claims.

What is claimed is:

1. A Non-volatile ROM (NROM), comprising:
a plurality of gate patterns in which a dielectric layer and gate conductive layers are stacked over a semiconductor substrate;
a plurality of first and second junction regions formed in active regions between the plurality of gate patterns;
a plurality of first contact plugs respectively connected to a plurality of the first junction regions of a diagonal direction, which are non-adjacent to one another;
a plurality of second contact plugs respectively connected to a plurality the second junction regions of a diagonal direction, which are non-adjacent to one another;
a plurality of first metal lines to connect the first contact plugs that are adjacent to each other in a diagonal direction; and
a plurality of second metal lines to connect the second contact plugs that are adjacent to each other in a diagonal direction.

2. The NROM of claim 1, wherein the gate conductive layers are formed of a polysilicon layer.

3. The NROM of claim 1, wherein the dielectric layer has an ONO (oxide-nitride-oxide) structure formed of a first oxide layer, a nitride layer and a second oxide layer.

4. The NROM of claim 1, wherein the first contact plugs are in a diamond shape.

5. The NROM of claim 1, wherein the second contact plugs are in a diamond shape.

6. The NROM of claim 1, further comprising a spacer formed over sidewalls of the plurality of gate patterns.

7. A method of fabricating NROM, comprising the steps of:
forming isolation structures in a semiconductor substrate;
forming a dielectric layer in an active region of the semiconductor substrate;
forming gate conductive layers over the semiconductor substrate including the dielectric layer;
etching the gate conductive layers and the dielectric layers to form gate patterns;
forming first and second junctions in the active region of the semiconductor substrate between the gate patterns;
forming an insulating layer over the semiconductor substrate including the gate patterns;
etching the insulating layer which is non-adjacent to each other in a diagonal direction, to form first contact plugs connecting the first junctions;
forming first metal lines to connect the first contact plugs;
etching the insulating layers which non-adjacent to each other between the first contact plugs to form second contact plugs connecting the second junctions; and
forming second metal lines to connect the second contact plugs.

8. The method of claim 7, further comprising the step of, forming a spacer on sidewalls of the gate patterns after the first and second junction regions are formed.

9. The method of claim 7, further comprising the steps of:
forming third contact plugs to connect the first and the second metal lines after forming the second metal lines; and
forming third metal lines to connect the third contact plugs.

10. The method of claim 7, further comprising the steps of, forming a first oxide layer, a nitride layer and a second oxide layer over semiconductor substrate including the isolation structure; and
etching the first oxide layer, the nitride layer and the second oxide layer to remain in the active regions of the semiconductor substrate.

11. The method of claim 7, wherein the gate conductive layers are formed of a polysilicon layer.

12. The method of claim 7, wherein the first contact plugs are in a diamond shape.

13. The method of claim 7, wherein the second contact plugs are in a diamond shape.
